(19) United States
(12) Patent Application Publication
(10) Pub. No.: US 2026/0279720 A1
(43) Pub. Date: Sep. 17, 2026

(54) CHARGED PARTICLE BEAM DEVICE AND METHOD

(71) Applicant: ICT Integrated Circuit Testing Gesellschaft für Halbleiterprüftechnik mbH, Heimstetten (DE)

(72) Inventors: Benjamin Cook, Putzbrunn (DE); Ivo Liska, Haar (DE); Idan Tamir, Herzliya (IL)

(73) Assignee: ICT Integrated Circuit Testing Gesellschaft für Halbleiterprüftechnik mbH, Heimstetten (DE)

(21) Appl. No.: 19/078,121

(22) Filed: Mar. 12, 2025

(51) Int. Cl. H01J 37/153; H01J 37/10; H01J 37/147; H01J 37/28

(52) U.S. Cl. CPC H01J 37/153; H01J 37/10; H01J 37/1474; H01J 37/28; H01J 2237/1534

(57) ABSTRACT

A charged particle beam device having an optical axis and comprising: a charged particle source for providing a primary charged particle beam; a deflector arrangement configured to provide a tilted primary charged particle beam and to guide signal charged particles comprising: a first deflector, a second deflector positioned downstream of the first deflector, a third deflector positioned downstream of the second deflector, a fourth deflector positioned downstream of the third deflector; a first detector comprising a first detection area for detecting signal charged particles and positioned upstream of the second deflector; an objective lens for focusing the primary charged particle beam onto a sample to generate the signal charged particles.

### TECHNICAL FIELD

The present disclosure relates to a charged particle beam device, particularly, to a charged particle beam device configured to provide a tilted primary charged particle beam and to guide signal charged particles, and an according method.

### BACKGROUND

Charged particle beam apparatuses have many functions, in a plurality of industrial fields, including, but not limited to, critical dimensioning of semiconductor devices during manufacturing, defect review of semiconductor devices during manufacturing, inspection of semiconductor devices during manufacturing, exposure systems for lithography, detecting devices and testing systems. Thus, there is a high demand for structuring, testing and inspecting specimens or samples within the micrometer and nanometer scale.

Micrometer and nanometer scale process control, inspection or structuring is often done with charged particle beams, e.g. electron beams, which are generated and focused in charged particle beam devices, such as electron microscopes or electron beam pattern generators. Providing a charged particle beam as a primary charged particle beam on a sample may induce that signal charged particles are emitted from the sample which may be detected by a detector of the charged particle beam device for analyzing the sample.

In some cases, it may be beneficial to provide a tilted primary charged particle beam on the sample. For example, by providing a tilted primary charged particle beam, the sample may be analyzed from an angle (e.g., without tilting the sample mechanically). In known approaches, the primary charged particle beam may be deflected by a deflector to provide a tilted primary charged particle beam on the sample. In such a case, the signal charged particles emitted from the sample may be exposed to the deflection of the charged particle beam device, as well, which may adapt the path of the signal charged particles to the deflector of the charged particle beam device.

A reliable control of the signal charged particles may be beneficial to enable a reliable functioning of a charged particle beam device, particularly, a charged particle beam device configured to provide a tilted primary charged particle beam on a sample.

### SUMMARY

In light of the above, an apparatus for a charged particle beam device, and a method are provided. Further aspects, advantages, and features are apparent from the dependent claims, the description, and the accompanying drawings.

A first aspect relates to a charged particle beam device having an optical axis, comprising: a charged particle source for providing a primary charged particle beam; a deflector arrangement configured to provide a tilted primary charged particle beam and to guide signal charged particles comprising: a first deflector, a second deflector positioned downstream of the first deflector, a third deflector positioned downstream of the second deflector, a fourth deflector positioned downstream of the third deflector; a first detector comprising a first detection area for detecting signal charged particles and positioned upstream of the second deflector; an objective lens for focusing the primary charged particle beam onto a sample to generate the signal charged particles.

A second aspect relates to a method comprising: providing a primary charged particle beam by a charged particle source; focusing the primary charged particle beam onto a sample by an objective lens; deflecting the primary charged particle beam by a deflector arrangement having four deflectors such that the primary charged particle beam is provided as a tilted primary charged particle beam on the sample; deflecting signal charged particles emitted from the sample by the deflector arrangement such that the signal charged particles are guided onto a first detection area of the first detector.

### BRIEF DESCRIPTION OF THE DRAWINGS

So that the manner in which the above recited features can be understood in detail, a more particular description, briefly summarized above, may be had by reference to embodiments. The accompanying drawings relate to embodiments and are described in the following:

FIG. 1 shows a schematic view of a charged particle beam device according to some embodiments of the present disclosure, the charged particle beam device having a deflector arrangement with four deflectors;

FIG. 2 shows a schematic view of a charged particle beam device having a deflector arrangement with three deflectors according to some embodiments;

FIG. 3 shows a schematic view of a charged particle beam device according to further embodiments of the present disclosure, the charged particle beam device having a deflector arrangement with four deflectors;

FIG. 4 shows a schematic view of a charged particle beam device according to further embodiments of the present disclosure, the charged particle beam device having a deflector arrangement with four deflectors; and

FIG. 5 shows a block diagram of a method according to some embodiments of the present disclosure.

### DETAILED DESCRIPTION OF THE INVENTION

Reference will now be made in detail to the various embodiments, one or more examples of which are illustrated in the figures.

In some examples, the present invention relates to a charged particle beam device for providing a tilted charged particle beam on a sample, the charged particle device having at least four deflectors positioned along an optical axis of the charged particle device to provide a high degree of freedom for adapting a path of charged particles within the charged particle beam device (e.g., signal charged particles and/or charged particles of a primary charged particle beam). The at least four deflectors may be positioned along the optical axis of the charged particle device. For example, the charged particle beam device according to the present disclosure may comprise a first deflector, a second deflector positioned downstream of the first deflector, a third deflector positioned downstream of the second deflector, a fourth deflector positioned downstream of the third deflector. The herein described deflector arrangement of the charged particle beam device having at least four deflectors may provide that different types of charged particles can be adapted with a high degree of freedom to travel onto a respective detector of the charged particle beam device. Such a configuration may be beneficial for analyzing the sample with the tilted charged particle beam of the charged particle beam device.

Within the following description of the drawings, the same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

Without limiting the scope of protection of the present application, in the following the charged particle beam device may comprise an electron beam device configured to provide a primary charged particle beam (e.g. a primary electron beam) and to detect signal charged particles (e.g., signal electrons such as secondary electrons and/or backscattered electrons) emitted from a sample. The embodiments described herein can also be applied for apparatuses and components detecting corpuscles such as secondary and/or backscattered charged particles in the form of electrons or ions, photons, X-rays or other signals in order to obtain a sample image or inspection result.

A “specimen”, “sample” or “wafer” as referred to herein, includes, but is not limited to, semiconductor wafers, semiconductor workpieces, and other workpieces such as memory disks and the like. Embodiments may be applied to any workpiece which is structured or on which material is deposited. A specimen, a sample or wafer may include a surface to be imaged and/or structured or on which layers are deposited, an edge, and/or a bevel. According to some embodiments, which can be combined with other embodiments described herein, the apparatus and methods are configured for or are applied for critical dimension measurement and defect review applications. Embodiments may also refer to electron beam inspection (EBI), where the microscopes according to embodiments described herein can be beneficially used in light of the desire for high throughput of the named applications. A wafer imaging system or a wafer SEM inspection tool refers to EBI tools, critical dimension (CD) tools or defect review (DR) tools, which are specific tools as understood by a person skilled in the art.

The present disclosure relates to a charged particle beam device that is configured to provide a tilted primary charged particle beam and to guide signal charged particles onto a detector. Particularly, the tilted primary charged particle beam may be provided at a tilted landing angle on an area of the sample to analyze the sample from the side (e.g., without mechanically tilting the sample). A deflection of the primary charged particle beam is implemented by a deflector of the charged particle beam to provide the tilted landing angle. Signal charged particles emitted from the area of the sample are then guided to a detector for imaging the sample. The detector may reside within the charged particle beam device such that the signal charged particles are to be guided into the direction from which the primary charged particle beam is provided to ensure that the signal charged particles may impinge on the detector. The effects of the deflection of the primary charged particle beam may, thus, at least in part be affected onto the signal charged particles, as well (e.g., by a deflection of the signal charged particles as they travel towards the detector).

According to the present disclosure a charged particle beam device with a deflector arrangement is provided comprising four deflectors to control the primary charged particle beam and the signal charged particle beam such that a tilted primary charged particle beam can be provided on the sample wherein the signal charged particles may be guided to the detector in a beneficial manner. For example, with the deflector arrangement having four deflectors, a higher degree of freedom to control the primary charged particle beam and the signal charged particles may be provided. According to the present disclosure, it may be facilitated that even for a wider range of tilt angles of the primary charged particle beam, the signal charged particles may be guided onto the detector for detection. According to the present disclosure the amount of detected signal charged particles may be increased at least in part for a wider range of tilted landing angles. Furthermore, the amount of signal charged particles deflected away from the detector may be reduced at least in part for a wider range of tilted landing angles. Moreover, the wider degree of freedom may enable to also address optical errors in a defined manner, particularly for applications with a wider spectrum of tilted landing angles.

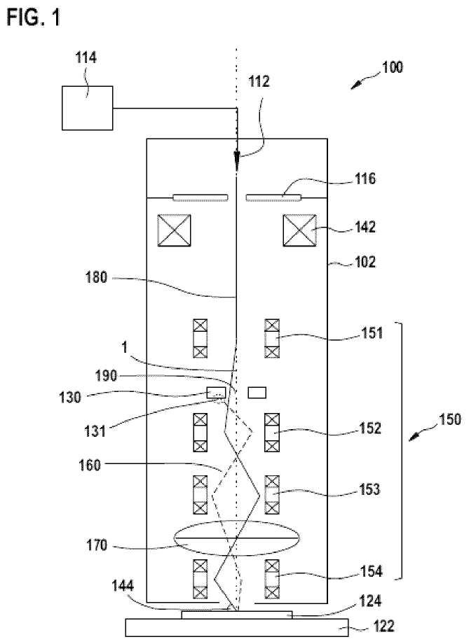

FIG. 1 shows a schematic view of a charged particle beam device according to embodiments of the present disclosure.

A first aspect of the present disclosure relates to a charged particle beam device 100 having an optical axis 1, comprising: a charged particle source 112 for providing a primary charged particle beam 180; a deflector arrangement 150 configured to provide a tilted primary charged particle beam and to guide signal charged particles 160 comprising: a first deflector 151, a second deflector 152 positioned downstream of the first deflector 151, a third deflector 153 positioned downstream of the second deflector 152, a fourth deflector 154 positioned downstream of the third deflector 153. The charged particle beam device 100 further comprising: a first detector 130 comprising a first detection area 131 for detecting signal charged particles 160 and positioned upstream of the second deflector 152; an objective lens 170 for focusing the primary charged particle beam 180 onto a sample 124 to generate the signal charged particles 160.

The charged particle beam device 100 may include an SEM (scanning electron microscope) imaging apparatus. For example, the SEM imaging apparatus may be configured as a wafer imaging system. A beam column of the charged particle beam device 100, e.g. column 102, may include a first chamber, and at least one further chamber. The first chamber, which can also be referred to as a gun chamber, may include the charged particle source 112 (e.g., an electron source) having an emitter and, for example, a suppressor. In an example, where the charged particle source 112 is an electron source, the primary charged particle beam may include a primary electron beam. In the present disclosure, examples are made with respect to a primary electron beam, however, the disclosure may also encompass other charged particles in the primary charged particle beam depending on the type of charged particle source provided (e.g., the primary charged particle beam may also be an ion beam if an ion source is provided as a charged particle source).

The deflector arrangement 150, the first detector 130 and the objective lens 170 may be positioned within one or more other chambers of the charged particle device that are different from the first chamber, the gun chamber. For example, it may be beneficial to provide the deflector arrangement 150, the first detector 130 and the objective lens 170 in other vacuum regions of the charged particle device to segregate the gun chamber from these components.

According to embodiments described herein, the emitter of the charged particle source 112 may be connected to a power supply 114 for providing a voltage to the emitter, for example an acceleration voltage to accelerate charge particles from the emitter.

In an example, the primary charged particle beam 180 generated by the charged particles source 112 may be aligned to a beam limiting aperture 116 that is dimensioned to shape the beam. For example, the beam limiting aperture 116 may block a portion of the primary charged particle beam 180. The beam may then pass through the one or more chambers of the column 102.

In an example, the primary charged particle beam 180 coming from the charged particle source 112 may be deflected by the deflectors of the deflector arrangement 150. For example, the primary charged particle beam 180 coming from the charged particle source 112 may be deflected by the first deflector 151. Subsequently, the primary charged particle beam 180 may be deflected by the second deflector 152. Subsequently, the primary charged particle beam 180 may be deflected by the third deflector 153. Subsequently, the primary charged particle beam 180 may be deflected by the fourth deflector 154. Particularly, the fourth deflector may be configured to provide the primary charged particle beam at a tilted landing angle 144 on the sample 124.

The deflectors 151, 152, 153, 154 of the deflector arrangement 150 may include electrostatic and/or magnetic deflectors suitable to deflect charged particles (e.g., negatively or positively charged particles).

According to some embodiments, which can be combined with other embodiments described herein, a condenser lens 142 may be provided in the charged particle beam device 100. The deflector arrangement 150 may be provided downstream of the condenser lens 142.

In an example, the primary charged particle beam 180 may be focused on the sample 124 by the objective lens 170. The objective lens 170 may include a magnetic lens. The magnetic lens may include a coil, e.g., a wire arranged in a certain winding arrangement, with the coil being configured for generating the magnetic field of the magnetic lens.

The sample 124 may be positioned on a sample position on the sample stage 122. On impingement of the primary charged particle beam 180 on the sample 124 signal charged particles 160 (e.g., secondary or backscattered electrons) may be released from the sample 124.

The signal charged particles 160 may be released to at least one of the deflectors of the deflector arrangement 150. In an example, the deflector arrangement 150 may be configured to deflect signal charged particles 160 emitted from the sample such that the signal charged particles 160 are guided onto the first detection area 131 of the first detector 130. For example, the signal charged particles may be released to the fourth deflector 154 with the fourth deflector 154 deflecting the signal charged particles to at least one further deflector of the deflector arrangement 150 such that the signal charged particles are guided on the first detection area 131 of the first detector 130.

In an embodiment, which may be combined with other embodiments described herein, the charged particle beam device 100 may be configured to set a working state of the deflector arrangement 150, the working state comprising a deflection state for each deflector 151, 152, 153, 154 of the deflector arrangement 150, wherein in the working state: the primary charged particle beam 180 is deflected by the deflector arrangement 150 at least four times; and the signal charged particles are deflected by the deflector arrangement 150 at least three times. Accordingly, the deflector arrangement 150 may provide a degree of freedom for controlling the primary charged particles and the signal charged particles.

In an example, the primary charged particle beam 180 may undergo one more deflection by the deflection arrangement 155 than the signal charged particles (e.g., the primary charged particles may be deflected four times by the deflector arrangement 150 whereas the signal charged particles are deflected by the deflector arrangement three times).

In some embodiments, the charged particle beam device 100 may be configured to set a working state of the deflector arrangement 150, the working state comprising a deflection state for each deflector 151, 152, 153, 154 of the deflector arrangement 150, wherein in the working state: the primary charged particle beam 180 is deflected by at least four different deflectors of the deflector arrangement; the signal charged particles 160 are deflected by at least three different deflectors of the deflector arrangement. Accordingly, the deflector arrangement 150 may provide a degree of freedom for controlling the primary charged particles and the signal charged particles. Particularly, four degrees of freedom are provided to allow for three conditions for deflecting the primary charged particle bean and to allow for guiding the signal charged particles on the detector as a fourth condition.

In an example, in the working state, the primary charged particle beam 180 may be deflected by at least one more deflector of the deflector arrangement than the signal charged particles (e.g., the primary charged particles may be deflected by four different deflectors of the deflector arrangement 150 whereas the signal charged particles may be deflected by three different deflectors of the deflector arrangement). For example, the primary charged particles may be deflected by the first deflector 151, the second deflector 152, the third deflector 153 and the fourth deflector 154, wherein the signal charged particles may be deflected by the fourth deflector 154, the third deflector 153, and the second deflector 152.

The herein described working state of the deflector arrangement 150 may provide an asymmetry with respect to the deflections of the primary charged particle beam and the signal charged particles, while providing a variety of deflections to each of the primary charged particle beam and the signal charged particle beam (i.e., at least four deflection to control the primary charged particle beam, and at least three deflection to control the signal charged particles). This degree of freedom may be beneficial, particularly, for ensuring that the amount of signal charged particles to be guided onto the first detector is beneficial while enabling a (e.g., focused) tilted primary charged particle beam on the sample.

In an example, in the working state, the deflection state for each of the deflectors 151, 152, 153, 154 of the deflector arrangement 150 may be the same when deflecting the primary charged particle beam 180 and the signal charged particles 160. For example, each of the deflectors 151, 152, 153, 154 may be set to evoke a specific deflection state of the primary charged particle beam 180, wherein the setting for deflecting the primary charged particle beam 180 is also used to deflect the signal charged particles 160. For example, the first deflector 151 may be set to a first deflection state, the second deflector 152 may be set to a second deflection state, the third deflector 153 may be set to a third deflection state, the fourth deflector 154 may be set to a fourth deflection state. The first, second, third and fourth deflection state may be set for deflecting the primary charged particle beam 180 and the signal charged particles 160. This may avoid changing the deflection state during the analyzing of the sample by the charged particle device while ensuring that the primary charged particle beam is provided at a tilted landing angle and the signal charged particles are guided to the first detector 130 for detection in a beneficial manner.

In some embodiments, the charged particle beam device 100 may be configured that in the working state: the signal charged particles 160 are not deflected by the first deflector 151. For example, the primary charged particles may be deflected by the first deflector 151, the second deflector 152, the third deflector 153 and the fourth deflector 154, wherein the signal charged particles may be deflected by the fourth deflector 154, the third deflector 153, and the second deflector 152, wherein the signal charged particles are not deflected by the first deflector 151. This configuration may be provided by the deflection states of the deflectors of the deflector arrangement 150, the deflection states set such that the signal charged particles are not guided to the first deflector 151 (e.g., since the signal charged particles may be substantially guided onto the first detector 130 by the fourth deflector 154, the third deflector 153, and the second deflector 152). In an example, in the working state: the signal charged particles 160 may not be deflected by the first deflector, with the first detector 130 being positioned between the first deflector 151 and the second deflector 152 (as described herein).

In some embodiments, the first deflector 151 may be positioned between the charged particle source 112 and the second deflector 152; the second deflector 152 may be positioned between the first deflector 151 and the third deflector 153; the third deflector 153 may be positioned between the second deflector 152 and the fourth deflector 154; the objective lens 170 may be positioned between the third deflector 153 and the fourth deflector 154. In this example, particularly, the fourth deflector 154 may facilitate a contribution that the primary charged particle beam 180 is provided at the tilted landing angle on the sample 124, as the fourth deflector 154 may deflect the primary charged particle beam after the primary charged particle beam 180 has been deflected by the first, second and third deflectors 151, 152, 153 and focused by the objective lens 170.

In some embodiments, the first detector 130 may be positioned between the first deflector 151 and the second deflector 152. This example may be beneficial, as with the positioning of the first detector 130 between the first and second deflector, the fourth deflector 154, the third deflector 153 and the second deflector 152 are positioned downstream of the first detector, and the first deflector 151 is positioned upstream of the first detector 130. With such a positioning, the configuration of the deflector arrangement 150 may be set, such that, in particular, the fourth deflector 154, the third deflector 153 and the second deflector 152 guide the signal charged particles 160 onto the first detector 130, with the influence of the first deflector 151 on the signal charged particles being reduced completely or at least in part. For example, in the working state the signal charged particles 160 may not be deflected by the first deflector 151, when the first detector 130 is positioned between the first deflector 151 and the second deflector 152. The herein described positioning approach may be beneficial for providing a wide range of a tilted landing angle of the primary charged particle beam and detecting the corresponding signal charged particles emitted from the sample.

In some embodiments, the deflector arrangement 150 may be configured to deflect the primary charged particle beam 180 such that a chromatic aberration of the primary charged particle beam is reduced at least in part. For example, a subset or a single deflector of the deflector arrangement 150 may be configured to reduce a chromatic aberration of the primary charged particle beam at least in part.

For example, tilting of the charged particle beam can cause chromatic aberration. The subset or single deflector of the deflector arrangement 150 may be configured to introduce a compensating dispersion to reduce the chromatic aberration. For example, this may be provided by an according setting of a magnetic deflection element of the subset or single deflector of the deflector arrangement 150. For example, the compensation dispersion may be provided by an ExB-type configuration that includes the magnetic deflection element, and that can provide an electric field and a magnetic field to introduce the compensating dispersion.

In an example, the first deflector 151 may be configured to deflect the primary charged particle beam 180 such that a chromatic aberration of the primary charged particle beam is reduced at least in part. In other examples, other deflectors or sets of deflectors of the deflector arrangement 150 may be set to reduce the chromatic aberration of the primary charged particle beam at least in part. For example, all deflectors 151, 152, 153, 154 of the deflector arrangement 150 may be set to contribute to a reduction of the chromatic aberration.

In some embodiments, the charged particle beam device may be configured to provide the primary charged particle beam to the first deflector 151, the first deflector 151 configured to deflect the primary charged particle beam away from the optical axis 1. As shown in FIG. 1, the first deflector 151 may be configured to deflect the primary charged particle beam 180 away from the optical axis 1, with the primary charged particle beam 180 being provided to the first deflector 151 along the optical axis 1.

In some embodiments, the first deflector 151 may be configured to guide the primary charged particle beam 180 through an aperture 190 of the first detector 130 to the second deflector 152. Such a configuration may be beneficial as the aperture 190 may provide a segregation of the first deflector 151 from the second deflector 152, the third deflector 153 and the fourth deflector 154 to a certain degree which may provide a further degree of freedom for adapting the primary charged particle beam 180 and the signal charged particles 160 by the deflector arrangement 150.

Particularly, the herein described aperture 190 may provide that the first detector 130 can be positioned between the first deflector 151 and the second deflector 152. As described herein, with such a positioning, the configuration of the deflector arrangement 150 may be set, such that, in particular, the fourth deflector 154, the third deflector 153 and the second deflector 152 guide the signal charged particles 160 onto the first detector 130, with the influence of the first deflector 151 on the signal charged particles being reduced completely or at least in part.

In some embodiments, the second deflector 152 may be configured to deflect the primary charged particle beam coming from the first deflector 151 to the third deflector 153; and the second deflector 152 may be configured to deflect the signal charged particles 160 coming from the third deflector 153 onto the first detection area 131 of the first detector 130.

As described herein, the deflection states of each of the deflectors of the deflector arrangement 150 may remain the same when providing the primary charged particle beam 180 at a tilted landing angle on the sample 124 and when guiding the signal charged particles to the first detector. The deflection states may be set (e.g., via a predetermined calculation) to provide that the primary charged particles and the signal charged particles are guided to their respective destinations (as described herein). Particularly, the deflection state of the second deflector 152 is described in the above-mentioned example, since the second deflector 152 may be the deflector of the deflector arrangement 150 that may be the closest to the first detector 130 downstream from the first detector 130 (as can be seen in the example of FIG. 1). The deflection state of the second deflector 152 may be set to ensure that the amount of signal charged particles 160 deflected onto the first detection area 131 of the first detector 130 may be beneficial for analyzing the sample 124. For example, the deflection state of the second deflector 152 may be set to have the boundary condition that the amount of signal charged particles 160 impinging onto the first detection area 131 of the first detector 130 is beneficial, for example, that the amount of signal charged particles 160 impinging on the first detector 130 is high for a given spectrum of tilted landing angles of the primary charged particle beam 180.

In an embodiment, which may be combined with other embodiments described herein, the second deflector 152 may be configured to deflect the primary charged particle beam 180 across the optical axis 1 (as shown in FIG. 1).

In some embodiments, at least one deflector of the deflector arrangement 150 may be configured to deflect the primary charged particle beam 180 such that an optical aberration associated with the objective lens 170, particularly a coma, is reduced at least in part.

For example, the at least one deflector of the deflector arrangement 150 may be configured to guide the primary charged particle beam 180 by the deflection through a (substantially) coma-free position of the objective lens 170 to reduce the coma. The (substantially) coma-free position may, for example, be at a position of (or provided by) the objective lens 170. The (substantially) coma-free position may be a point at which substantially a minimum or even no coma is introduced to the primary charged particle beam 180 when the primary charged particle beam 180 passes through the objective lens 170. The (substantially) coma-free position may be located on the optical axis 1 which may be defined by the objective lens or the charged particle beam device 100. In an example, the (substantially) coma-free position may be positioned in front of a lens center or a lens field center of the objective lens 170. In some examples, the (substantially) coma-free position can be surrounded by the objective lens 170.

In some embodiments, the third deflector 153 may be configured to deflect the primary charged particle beam 180 across the optical axis 1 (as shown in FIG. 1).

In some embodiments, the third deflector 153 may be configured such that the primary charged particle beam 180 is guided across the optical axis 1 through the (herein described) substantially coma-free position of the objective lens 170. For example, as exemplarily shown in FIG. 1, the third deflector 153 may be the deflector of the deflector arrangement 150 that is positioned closest to the objective lens 170 upstream of the objective lens 170. The deflection of the third deflector 153 may be set to ensure that the primary charged particle beam 180 can be guided across the optical axis through the herein described substantially coma-free position of the objective lens 170. For example, a boundary condition of the third deflector 153 may be that the third deflector 153 is the deflector of the deflector arrangement 150 that provides the guidance or deflection of the primary charged particle beam 180 through the substantially coma-free position.

In some embodiments, the objective lens 170 may be configured to focus the primary charged particle beam 180 through the fourth deflector 154 onto the sample; the fourth deflector 154 may be configured to deflect the primary charged particle beam 180 such that the primary charged particle beam 180 is provided at a tilted landing angle 144 on the sample 124.

In an example, the fourth deflector 154 may be configured as a post-lens deflector positioned downstream of the objective lens 170. For example, the at least one deflector of the deflector arrangement 150 (e.g., the third deflector 153) may be configured to guide the primary charged particle beam 180 by the deflection through a (substantially) coma-free position of the objective lens 170 to reduce the coma, with the fourth deflector 154 being positioned downstream of the objective lens 170 and configured to tilt the primary charged particle beam 180 to provide the primary charged particle beam 180 at tilted landing angle 144 on the sample 124.

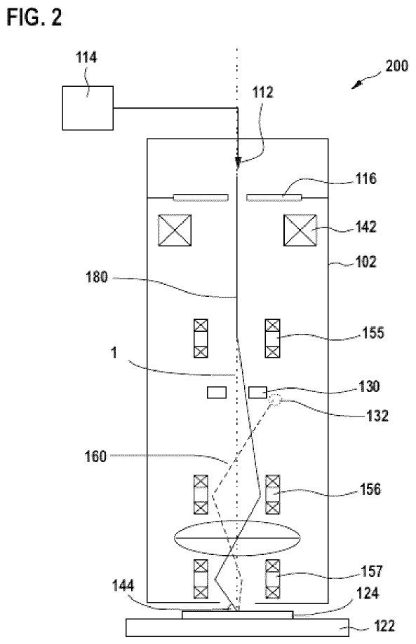

FIG. 2 shows a schematic view of a second charged particle beam device 200 having a deflector arrangement with three deflectors (also termed herein second-device deflector arrangement). FIG. 2 is shown to compare the configuration of the charged particle device according to the present disclosure (as shown in FIG. 1) with an example of a second charged particle beam device 200, where the second-device deflector arrangement only has three deflectors (as shown in FIG. 2). Particularly, the deflector arrangement of FIG. 2 only has three deflectors, the second-device first deflector 155, the second-device second deflector 156, the second-device third deflector 157. The remaining parts of the second charged particle beam device 200 may substantially correspond to the parts described with respect to the charged particle beam device 100 according to the present disclosure and are not further discussed herein, for the sake of brevity (with the remaining parts being labeled in FIG. 2 as in FIG. 1).

As the second charged particle beam device 200 has a second-device deflector arrangement with only three deflectors 155, 156, 157 the second charged particle beam device 200 can provide fewer degrees of freedom to adapt the primary charged particle beam 180 and the signal charged particles 160. For example, for a particular set of tilted landing angles provided by the second-device deflector arrangement, it may be possible that the signal charged particles 160 may not impinge onto a detection area of the first detector 130. As shown in FIG. 2, signal charged particles 160 may be deflected into a zone 132 which is removed from the first detector 130. The signal charged particles 160 in the zone 132 of FIG. 2 may not be detected by the first detector 130. Depending on the amount of signal charged particles 160 deflected away from the first detector 130, no image or a bad quality image of the sample 124 may be provided by the second charged particle beam device 200. The deflecting of the signal charged particles 160 away from the first detector 130 may be particularly pronounced for larger landing angles 144 of the primary charged particle beam 180, as this typically requires more deflection of the primary charged particle beam 180 which may cause the signal charged particles 160 to be deflected onto a path away from the first detector 130. The second charged particle beam device 200 may, for example, not be suitable for larger landing angles 144 of the primary charged particle beam 180, as this would cause signal charged particles 160 to be deflected away from the first detector.

The aspects of the present disclosure may alleviate the described disadvantages at least in part, as more degree of freedom is provided to adapt the primary charged particle beam 180 and the signal charged particles 160 with a deflector arrangement including four deflectors, as described herein.

By providing a charged particle beam device 100 with four different deflectors, a higher technical complexity may be introduced, since more complex paths of the primary charged particle beam 180 and the signal charged particles 160 are to be considered, particularly, for a wider spectrum of tilted landing angles. Implementing the higher technical complexity may then provide the benefit that imaging of the sample is improved as the likelihood of signal charged particles impinging onto the detector is increased for the wider spectrum of tilted landing angles.

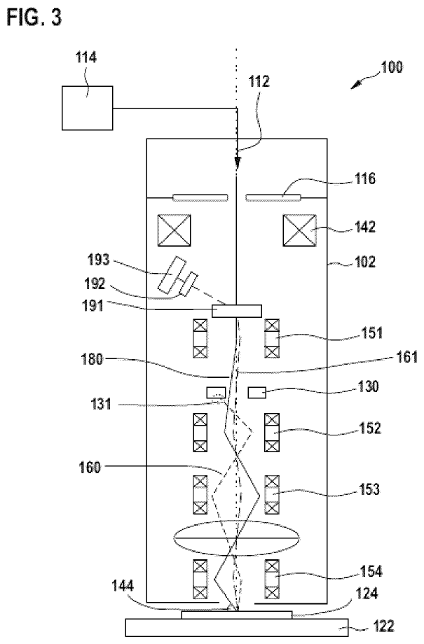

FIG. 3 shows a schematic view of a charged particle beam device 100 according to further embodiments of the present disclosure, the charged particle beam device having a deflector arrangement with four deflectors. Particularly, FIG. 3 shows an embodiment based on the embodiments of the charged particle beam device 100 described with respect to FIG. 1 with further features, according to the present disclosure. Features that were described with respect to the embodiments of FIG. 1, are labeled in FIG. 3 the same as in FIG. 1 and are not further described, for the sake of brevity. Particularly, the charged particle beam device 100 of FIG. 3 further comprises a second detector 193 and a beam separation unit 191.

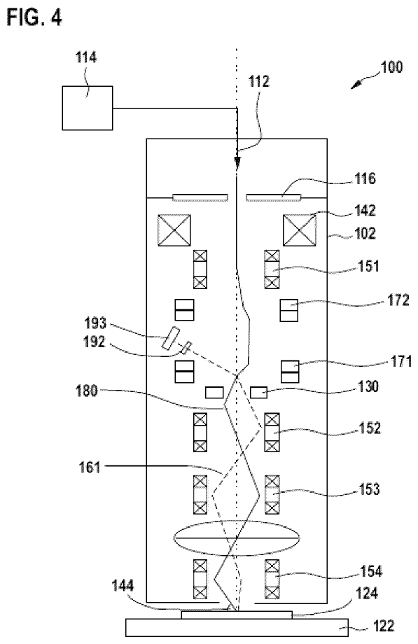

In some embodiments, the charged particle beam device 100 may further comprise: a second detector 193 comprising a second detection area for detecting further signal charged particles 161 and being positioned between the charged particle source 112 and the first detector 130; the deflector arrangement 150 further comprising: a beam separation unit 191 positioned between the charged particle source 112 and the first detector 130, the beam separation unit 191 configured to guide the further signal charged particles 161 onto the second detection area of the second detector 193 (for example, as shown in FIGS. 3 and 4).

For example, the charged particle beam device 100 may be configured such that the first detector 130 may detect signal charged particles 160 of a first type. The signal charged particles 160 of the first type may include signal charged particles in a first energy range or signal charged particles of a particular category (e.g., either backscattered electrons or secondary electrons). To account for the detection of other types of signal charged particles, the charged particle beam device 100 may be configured to also detect the further signal charged particles 161 which may be of a second type, different from the first type. For example, the trajectory of the further signal charged particles 161 may behave differently than the signal charged particles 160 such that the configuration of the first detector 130 may not always be beneficial to also detect the further signal charged particles. In another example, the detection of the signal charged particles 160 and the further signal charged particles 161 may be optimized by using separate detectors for each type of signal charged particles. The further signal charged particles 161 may also be adapted by the deflectors of the deflector arrangement 150, as described herein for the signal charged particles 160. Furthermore, the further signal charged particles 161 may be deflected by the first deflector 151 (as shown in FIG. 3).

In an example, the detection of the further signal charged particles 161 may be provided by the beam separation unit 191. The primary charged particle beam 180 may travel from the charged particle source 112 to the beam separation unit 191 (which may be an angled path with respect to the optical axis 1 shown in FIG. 3). The primary charged particle beam 180 may then be deflected by the beam separation unit 191 to propagate further to the sample, with the primary charged particle beam 180 being deflected by the deflector arrangement 155. The further signal charged particles 161 emitted by the sample may then travel to the beam separation unit 191 (in the opposite direction of the primary charged particle beam 180). The beam separation unit 191 is adapted for separating the further signal charged particles 161 (and/or the signal charged particles 160) from the primary charged particle beam 180 by deflecting the further signal charged particles 161 away from the path of the primary charged particle beam 180 (as schematically shown in FIG. 3). The further signal charged particles 161 may travel from the beam separation unit 191 to an optical element 192. The optical element 192 may include one or more components configured to adapt the further signal charged particles 161 (e.g., the optical element 192 may include a beam bender, or secondary charged particle optics). After passing through the optical element 192, the further signal charged particles 161 may impinge on a second detection area of the second detector 193.

In some examples, the charged particle beam device 100 according to embodiments of FIG. 3 may be configured to switch between providing signal charged particles 160 at the first detector 130 and providing the further signal charged particles 161 at the second detector 193 (for example, by according deflection states of the deflector arrangement 150).

In an embodiment, which may be combined with other embodiments described herein, the deflector arrangement 150 may comprise a fifth deflector positioned between the emitter and the fourth deflector 154, and the fifth deflector being positioned either upstream or downstream with respect to any of the deflectors of the deflector arrangement 155. A deflector arrangement 155 with five deflectors may provide a further degree of freedom to adapt the primary charged particle beam 180 and the signal charged particles 160. For example, a further fine tuning of the path of the emitted charged particles and/or the signal charged particles may be provided by the fifth deflector. In a further example, a sixth deflector or one or more further deflectors may be positioned between the emitter and the fourth deflector 154 providing a further degree of freedom to adapt the primary charged particle beam 180 and the signal charged particles 160.

FIG. 4 shows a schematic view of a charged particle beam device 100 according to further embodiments of the present disclosure, the charged particle beam device having a deflector arrangement with four deflectors. Particularly, FIG. 4 is based on the embodiments of the charged particle beam device 100 described with respect to FIG. 1 and FIG. 3 with further features, according to the present disclosure. Features that were described with respect to the embodiments of FIG. 1 and FIG. 3, are labeled in FIG. 4 the same as in FIG. 1 and FIG. 3, and are not further described, for the sake of brevity.

Particularly, the charged particle beam device 100 according to embodiments of FIG. 4 further comprises a second detector 193 (as the embodiments according to FIG. 3) with the second detector 193 being positioned between the first deflector 151 and the second deflector 152. For example, the second detector 193 may be positioned between the first deflector 151 and the first detector 130.

The charged particle beam device 100 according to embodiments of FIG. 4 may comprise a beam separation unit comprising a first pair of deflectors, such as a first pair of 2B-deflectors 171, and a second pair of deflectors, such as a second pair of 2B-deflectors 172. The first and second pair of 2B-deflectors 171, 172 may be regarded a 4B-deflector unit configuration. The beam separation unit according to embodiments of FIG. 4 (e.g. comprising first and second pair of 2B-deflectors 171, 172) may be positioned between the first deflector 151 and the first detector 130. In an example, the second detector 193 may be positioned between the first pair of 2B-deflectors 171 and the first deflector 151. The first and second pair of 2B-deflectors may be configured to separate the primary charged particle beam 180 from the further signal charged particles 161 (and/or from the signal charged particles 160) to provide the further signal charged particles 161 at the second detector 193.

In some examples, the charged particle beam device 100 according to embodiments of FIG. 4 may be configured to switch between providing signal charged particles 160 at the first detector 130 (path of signal charged particles not shown in FIG. 4) and providing the further signal charged particles 161 at the second detector 193, with an exemplary path of the further signal charged particles 161 shown in FIG. 4. The configuration to switch between providing the signal charged particles 160 (e.g., of the first type) at the first detector and the further signal charged particles 161 (e.g., of the second type) at the second detector 193 may be implemented by according deflection states of the deflector arrangement 150.

In some examples, the deflector arrangement 150 may be configured such that signal charged particles 160 are provided at the first detector and the further signal charged particles 161 (e.g., being a different type of signal charged particles as described herein) are provided at the second detector 193 simultaneously.

In same examples, the beam separation unit as shown for FIG. 4 may only comprise a first pair of (2B)-deflectors 171, without the presence of a further pair of (2B)-deflectors, as the beam separation unit to provide the separation between primary charged particle beam and signal charge particles.

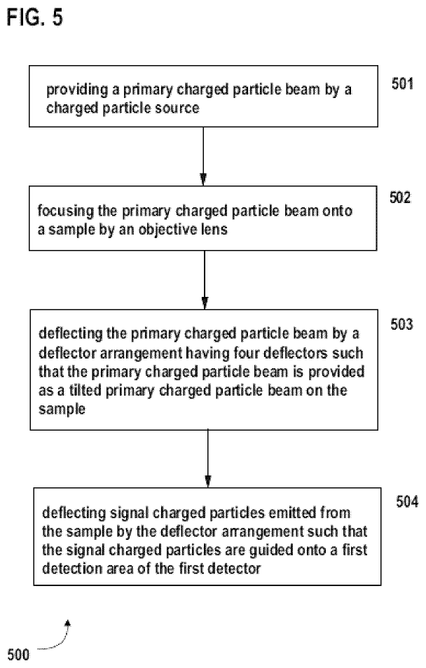

A second aspect of the present disclosure relates to a method. Particularly, FIG. 5 shows a block diagram of a method 500 according to embodiments of the present disclosure.

In some embodiments, the method 500 comprises: providing 501 a primary charged particle beam by a charged particle source; focusing 502 the primary charged particle beam onto a sample by an objective lens; deflecting 503 the primary charged particle beam by a deflector arrangement having four deflectors such that the primary charged particle beam is provided as a tilted primary charged particle beam, (e.g., with optimized resolution), on the sample; deflecting 504 signal charged particles emitted from the sample by the deflector arrangement such that the signal charged particles are guided onto a first detection area of the first detector.

In some embodiments, the method may further comprise: setting a working state of the deflector arrangement, the working state comprising a deflection state for each deflector of the deflector arrangement; in the working state, deflecting the primary charged particle beam by at least four different deflectors of the deflector arrangement; in the working state, deflecting the signal charged particles by at least three different deflectors of the deflector arrangement.

In some embodiments, the method may be performed with a charged particle beam device according to the first aspect.

A further aspect relates to a computer program for performing the method of the second aspect, particularly a non-transitory medium comprising instructions, that, when executed cause one or more processors to perform the method of the second aspect, specifically via a charged particle beam device of the first aspect.

The herein described charged particle beam device 100 of the first aspect may include a controller that is configured to control the components of the charged particle beam device 100 (e.g., to set the herein described working state of the deflector arrangement). Particularly, the controller (not shown) may be configured to execute the herein described method of the second aspect.

The controller can include a central processing unit (CPU), a memory and, for example, support circuits. To facilitate control of the charged particle beam device, the CPU may be one of any form of general purpose computer processor that can be used in an industrial setting for controlling various components of a charged particle beam device and sub-processors, for example deflectors of the deflector arrangement. The memory may be coupled to the CPU. The memory, or a computer readable medium, may be one or more readily available memory devices such as random access memory, read only memory, hard disk, or any other form of digital storage either local or remote. The support circuits may be coupled to the CPU for supporting the processor in a conventional manner. These circuits may include cache, power supplies, clock circuits, input/output circuitry and related subsystems, and the like. Inspecting process instructions are generally stored in the memory as a software routine typically known as a recipe. The software routine may also be stored and/or executed by a second CPU (not shown) that is remotely located from the hardware being controlled by the CPU. The software routine, when executed by CPU, may transform the general purpose computer into a specific purpose computer (controller) that controls the apparatus operation, such as that for controlling and/or setting the herein described deflector arrangement 150 of the herein described charged particle beam device.

Notably, features and aspects described herein with respect to an apparatus or device may also be accordingly applicable to the herein described methods or computer programs (and vice versa).

While the foregoing is directed to embodiments, other and further embodiments may be devised without departing from the basic scope, and the scope thereof is determined by the claims that follow.

Subsequently, further embodiments according to the present disclosure are described including the following embodiments.

Embodiment 1. A charged particle beam device (100) having an optical axis (OA), comprising:
a charged particle source (112) for providing a primary charged particle beam (180);
a deflector arrangement (150) configured to provide a tilted primary charged particle beam and to guide signal charged particles (160) comprising:
   a first deflector (151),
   a second deflector (152) positioned downstream of the first deflector,
a third deflector (153) positioned downstream of the second deflector,
   a fourth deflector (154) positioned downstream of the third deflector;
a first detector (130) comprising a first detection area (131) for detecting signal charged particles (160) and positioned upstream of the second deflector (152);
an objective lens (170) for focusing the primary charged particle beam (180) onto a sample (124) to generate the signal charged particles (160).

Embodiment 2. The charged particle beam device according to embodiment 1, the charged particle beam device configured to set a working state of the deflector arrangement (150), the working state comprising a deflection state for each deflector of the deflector arrangement, wherein in the working state:
the primary charged particle beam (180) is deflected by at least four different deflectors of the deflector arrangement;
the signal charged particles (160) are deflected by at least three different deflectors of the deflector arrangement.

Embodiment 3. The charged particle beam device according to embodiment 2, wherein the charged particle device is configured that in the working state: the signal charged particles (160) are not deflected by the first deflector.

Embodiment 4. The charged particle beam device according to any of embodiments 1-3;
the first deflector (151) positioned between the charged particle source (112) and the second deflector (152);
the second deflector (152) positioned between the first deflector and the third deflector;
the third deflector (153) positioned between the second deflector and the fourth deflector;
   the objective lens (170) positioned between the third and fourth deflector.

Embodiment 5. The charged particle beam device according to any of embodiments 1-4,
the first detector (130) positioned between the first deflector and the second deflector.

Embodiment 6. The charged particle beam device according to any of embodiments 1-5,
the deflector arrangement (150) being configured to deflect the primary charged particle beam such that a chromatic aberration of the primary charged particle beam is reduced at least in part.

Embodiment 7. The charged particle beam device according to any of embodiments 1-6,
at least one deflector of the deflector arrangement (150) configured to deflect the primary charged particle beam such that an optical aberration associated with the objective lens, particularly a coma, is reduced at least in part.

Embodiment 8. The charged particle beam device according to any of embodiments 1-7,
the charged particle beam device configured to provide the primary charged particle beam to the first deflector (151), the first deflector configured to deflect the primary charged particle beam (180) away from the optical axis (1).

Embodiment 9. The charged particle beam device according to embodiment 8, the first deflector (151) configured to guide the primary charged particle beam through an aperture (190) of the first detector (130) to the second deflector.

Embodiment 10. The charged particle beam device according to embodiment 9,
the second deflector (152) configured to deflect the primary charged particle beam coming from the first deflector to the third deflector; and
the second deflector (152) configured to deflect the signal charged particles coming from the third deflector onto the first detection area of the first detector.

Embodiment 11. The charged particle beam device according to any of embodiments 1-10,
the third deflector (153) configured to deflect the primary charged particle beam across the optical axis.

Embodiment 12. The charged particle beam device according to embodiment 11,
the third deflector (153) configured such that the primary charged particle beam is guided across the optical axis through a substantially coma-free position of the objective lens.

Embodiment 13. The charged particle beam device according to any of embodiments 1-12,
the objective lens (170) configured to focus the primary charged particle beam through the fourth deflector onto the sample; the fourth deflector configured to deflect the primary charged particle beam such that the primary charged particle beam is provided at a tilted landing angle on the sample.

Embodiment 14. The charged particle beam device according to any of embodiments 1-13, further comprising:
a second detector (193) comprising a second detection area for detecting further signal charged particles (161) and being positioned between the charged particle source and the first detector (130);
the deflector arrangement further comprising:
a beam separation unit (191) positioned between the charged particle source (112) and the first detector (130), the beam separation unit configured to guide the further signal charged particles onto the second detection area of the second detector.

Embodiment 15. A method comprising:
providing (501) a primary charged particle beam by a charged particle source;
focusing (502) the primary charged particle beam onto a sample by an objective lens;
deflecting (503) the primary charged particle beam by a deflector arrangement having four deflectors such that the primary charged particle beam is provided as a tilted primary charged particle beam on the sample;
deflecting (504) signal charged particles emitted from the sample by the deflector arrangement such that the signal charged particles are guided onto a first detection area of the first detector.

Embodiment 16. The method according to Embodiment 15,
the method further comprising:
setting a working state of the deflector arrangement, the working state comprising a deflection state for each deflector of the deflector arrangement;
in the working state, deflecting the primary charged particle beam by at least four different deflectors of the deflector arrangement;
in the working state, deflecting the signal charged particles by at least three different deflectors of the deflector arrangement.

Embodiment 17. The method according to any of embodiments 15-16, wherein the method is performed with a charged particle beam device (100) according to any of embodiments 1-14.

What is claimed is:

1. A charged particle beam device having an optical axis and comprising:
a charged particle source for providing a primary charged particle beam;
a deflector arrangement configured to provide a tilted primary charged particle beam and to guide signal charged particles comprising: a first deflector, a second deflector positioned downstream of the first deflector, a third deflector positioned downstream of the second deflector, and a fourth deflector positioned downstream of the third deflector;
a first detector comprising a first detection area for detecting signal charged particles and positioned upstream of the second deflector; and
an objective lens for focusing the primary charged particle beam onto a sample to generate the signal charged particles.

2. The charged particle beam device according to claim 1, wherein the charged particle beam device is configured to set a working state of the deflector arrangement, the working state comprising a deflection state for each deflector of the deflector arrangement, wherein in the working state:
the primary charged particle beam is deflected by at least four different deflectors of the deflector arrangement; and
the signal charged particles are deflected by at least three different deflectors of the deflector arrangement.

3. The charged particle beam device according to claim 2, wherein the charged particle device is configured such that in the working state, the signal charged particles are not deflected by the first deflector.

4. The charged particle beam device according to claim 1, wherein:
the first deflector is positioned between the charged particle source and the second deflector;
the second deflector is positioned between the first deflector and the third deflector;
the third deflector is positioned between the second deflector and the fourth deflector; and
the objective lens is positioned between the third and fourth deflector.

5. The charged particle beam device according to claim 2, wherein:
the first deflector is positioned between the charged particle source and the second deflector;
the second deflector is positioned between the first deflector and the third deflector;
the third deflector is positioned between the second deflector and the fourth deflector; and
the objective lens is positioned between the third and fourth deflector.

6. The charged particle beam device according to claim 3, wherein:
the first deflector is positioned between the charged particle source and the second deflector;
the second deflector is positioned between the first deflector and the third deflector;
the third deflector is positioned between the second deflector and the fourth deflector; and
the objective lens is positioned between the third and fourth deflector.

7. The charged particle beam device according to claim 1, wherein the first detector is positioned between the first deflector and the second deflector.

8. The charged particle beam device according to claim 1, wherein the deflector arrangement is configured to deflect the primary charged particle beam such that a chromatic aberration of the primary charged particle beam is reduced at least in part.

9. The charged particle beam device according to claim 1, wherein at least one deflector of the deflector arrangement is configured to deflect the primary charged particle beam such that an optical aberration associated with the objective lens, particularly a coma, is reduced at least in part.

10. The charged particle beam device according to claim 1, wherein the charged particle beam device is configured to provide the primary charged particle beam to the first deflector, the first deflector configured to deflect the primary charged particle beam away from the optical axis.

11. The charged particle beam device according to claim 10, wherein the first deflector is configured to guide the primary charged particle beam through an aperture of the first detector to the second deflector.

12. The charged particle beam device according to claim 11, wherein:
the second deflector is configured to deflect the primary charged particle beam coming from the first deflector to the third deflector; and
the second deflector is configured to deflect the signal charged particles coming from the third deflector onto the first detection area of the first detector.

13. The charged particle beam device according to claim 1, wherein the third deflector is configured to deflect the primary charged particle beam across the optical axis.

14. The charged particle beam device according to claim 13, wherein the third deflector is configured such that the primary charged particle beam is guided across the optical axis through a substantially coma-free position of the objective lens.

15. The charged particle beam device according to claim 1, wherein:
the objective lens is configured to focus the primary charged particle beam through the fourth deflector onto the sample; and
the fourth deflector configured to deflect the primary charged particle beam such that the primary charged particle beam is provided at a tilted landing angle on the sample.

16. The charged particle beam device according to claim 1, further comprising a second detector comprising a second detection area for detecting further signal charged particles, wherein the second detector is positioned between the charged particle source and the first detector; and
wherein the deflector arrangement further comprises a beam separation unit positioned between the charged particle source and the first detector, the beam separation unit being configured to guide the further signal charged particles onto the second detection area of the second detector.

17. A method comprising:
providing a primary charged particle beam by a charged particle source;
focusing the primary charged particle beam onto a sample by an objective lens;
deflecting the primary charged particle beam by a deflector arrangement having four deflectors such that the primary charged particle beam is provided as a tilted primary charged particle beam on the sample; and
deflecting signal charged particles emitted from the sample by the deflector arrangement such that the signal charged particles are guided onto a first detection area of a first detector.

18. The method according to claim 17, wherein the method is performed with a charged particle beam device according to claim 1.

19. The method according to claim 17, further comprising:
setting a working state of the deflector arrangement, the working state comprising a deflection state for each deflector of the deflector arrangement;
in the working state, deflecting the primary charged particle beam by at least four different deflectors of the deflector arrangement; and
in the working state, deflecting the signal charged particles by at least three different deflectors of the deflector arrangement.

20. The method according to claim 19, wherein the method is performed with a charged particle beam device according to claim 1.
